(19) United States
(12) Patent Application Publication
(10) Pub. No.: US 2026/0066784 A1
(43) Pub. Date: Mar. 5, 2026

(54) VOLTAGE CONVERTER AND METHOD FOR PRODUCING A VOLTAGE CONVERTER

(71) Applicant: Infineon Technologies Austria AG, Villach (AT)

(72) Inventor: Christian Stefan Rainer, Magdalensberg (AT)

(21) Appl. No.: 19/310,267

(22) Filed: Aug. 26, 2025

(30) Foreign Application Priority Data
Sep. 5, 2024 (EP) 24198616
Sep. 19, 2024 (EP) 24201402

(51) Int. Cl. H02M 3/155; H05K 1/02; H05K 1/11; H05K 1/14

(52) U.S. Cl. CPC H02M 3/155; H05K 1/0262; H05K 1/0298; H05K 1/11; H05K 1/142; H05K 2201/0335; H05K 2201/041

(57) ABSTRACT

A voltage converter is provided, comprising:
a first circuit board with a first circuit section of the voltage converter, wherein the first circuit section comprises semiconductor chips embedded between metal layers of the first circuit board, and
a second circuit section a second circuit board with a second circuit section of the voltage converter, wherein the first circuit section is electrically coupled to the second circuit section.

### RELATED APPLICATIONS

This application claims priority to earlier filed Europe Patent Application Serial Number EP24198616, filed on Sep. 5, 2024, the entire teachings of which are incorporated herein by this reference.

This application claims priority to earlier filed Europe Patent Application Serial Number EP24201402, filed on Sep. 19, 2024, the entire teachings of which are incorporated herein by this reference.

### TECHNICAL FIELD

The present application relates to voltage converters and methods for producing voltage converters.

### BACKGROUND

Voltage converters are circuits that convert an input voltage to an output voltage required for a particular application. One type of voltage converter is a direct current (DC/DC) converter that converts an input voltage to a DC output voltage.

Such DC/DC converters are required, for example, in accelerator cards for artificial intelligence (AI) applications. In this case, such DC/DC converters are provided directly on an accelerator card in order to enable precise voltage regulation and a fast response to load changes. This can provide a power supply that is optimized as far as possible for processors and other components of the accelerator card.

In this case, various converter topologies can be used, for example isolated or non-isolated topologies (that is to say with and without galvanic isolation between input side and output side, for example converters based on switched capacitors, LLC converters or step-down converters).

The space available on such accelerator cards for DC/DC converters is limited and in practice, even if this is not explicitly standardized, is usually currently 23 mmx 17 mm, that is to say a voltage converter module has to be accommodated on this area. Despite these size restrictions, the voltage converter has to offer good efficiency, that is to say low power losses, should be able to offer as high a power as possible and be able to enable the temperatures during operation to be kept within acceptable ranges. At the same time, the solution should be cost-effective.

### BRIEF DESCRIPTION

According to an embodiment, a voltage converter is provided, comprising:
a first circuit board with a first circuit section of the voltage converter, wherein the first circuit section comprises semiconductor chips formed between metal layers of the first circuit board, and
a second circuit board with a second circuit section of the voltage converter, wherein the first circuit section is electrically coupled to the second circuit section.

According to another embodiment, a method for producing a voltage converter is provided, comprising:
receiving a first circuit board with a first circuit section of the voltage converter, wherein the first circuit section comprises semiconductor chips embedded between metal layers of the first circuit board,
receiving a second circuit board with a second circuit section of the voltage converter, and
electrically coupling the first circuit section to the second circuit section.

The above summary provides only a brief overview of some embodiments and is not to be construed as limiting.

### BRIEF DESCRIPTION OF THE DRAWINGS

FIG. 1 is a schematic diagram of a voltage converter according to an embodiment.

FIG. 2A is a perspective view of a voltage converter according to an embodiment.

FIG. 2B is a side view of the voltage converter of FIG. 2A.

FIG. 2C is a top view of the voltage converter of FIGS. 2A and 2B.

FIG. 2D is a bottom view of the voltage converter of FIGS. 2A to 2C.

FIGS. 2E and 2F are sectional views in a circuit board of the voltage converter of FIGS. 2A to 2D.

FIG. 2G shows an alternative embodiment.

FIG. 3 is a cross-sectional view of a circuit board of a voltage converter according to some embodiments.

FIGS. 4A to 4C show a voltage converter according to an embodiment with a heat-conducting plate, wherein FIG. 4A shows a view corresponding to FIG. 2C and FIGS. 4B and 4C show views of the heat-conducting plate.

FIGS. 5A and 5B show details of the coupling between circuit boards in various embodiments.

FIG. 6 shows a circuit diagram of a voltage converter, with a division onto circuit boards according to some embodiments.

FIG. 7 shows a circuit diagram of a further voltage converter, with a division onto circuit boards according to some embodiments.

FIG. 8 shows a flow chart of a method according to some embodiments.

### DETAILED DESCRIPTION

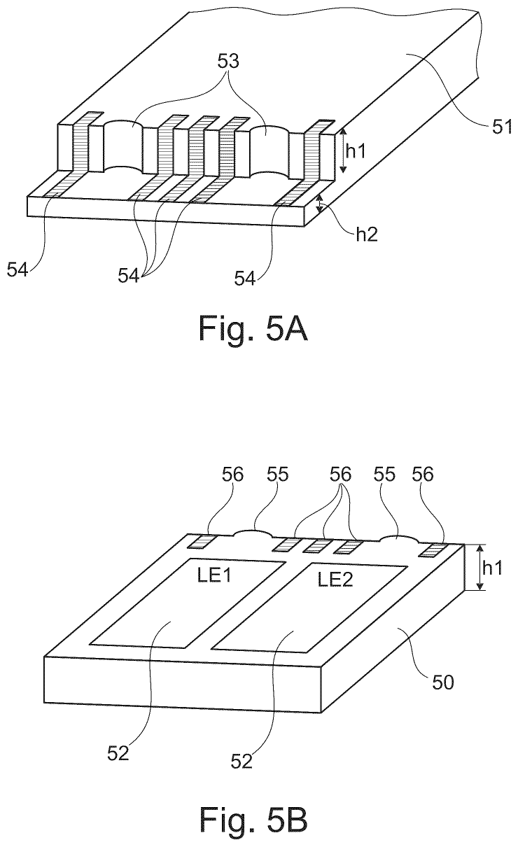

Various embodiments are explained in detail below. These exemplary embodiments serve for illustration and are not to be construed as limiting. Details, features or variations which are described for one of the exemplary embodiments are also applicable to other exemplary embodiments and are therefore not described repeatedly. Features of various exemplary embodiments described can be combined with one another, unless stated otherwise. Thus, for example, with reference to FIGS. 4A to 4C, a specific heat-conducting plate is described which is applicable in exemplary embodiments, and with reference to FIGS. 5A and 5B, a specific coupling between printed circuit boards is described. The heat-conducting plate and the coupling can be used independently of one another, but also jointly. The same applies to other described features.

In various exemplary embodiments described, a voltage converter circuit is divided into two circuit sections which are provided on different printed circuit boards. In this case, embedded semiconductor chips, that is to say semiconductor chips which are embedded between different metal layers of the printed circuit board, are used on one of the printed circuit boards. As will be described in more detail below, an improved implementation compared with the use of a single printed circuit board for the voltage converter circuit can be achieved hereby.

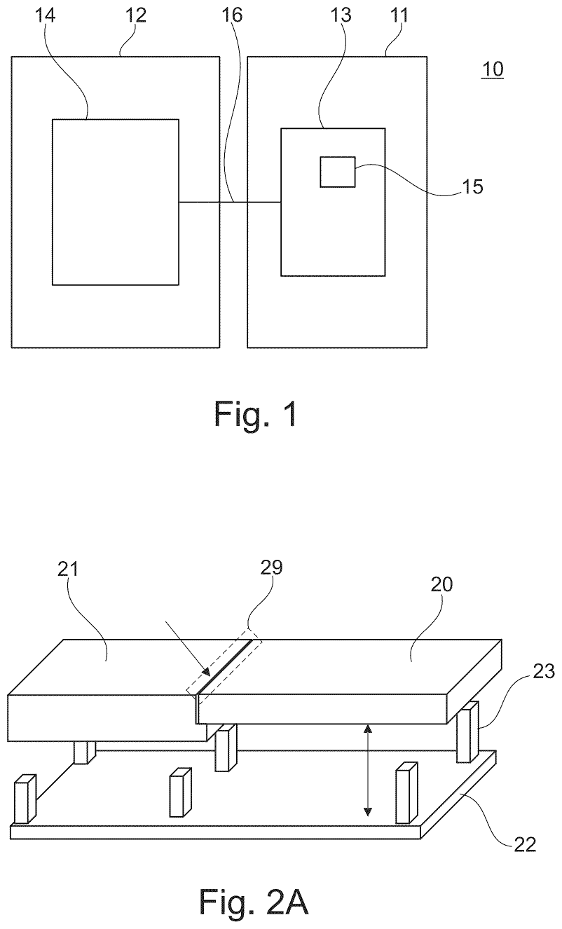

FIG. 1 shows a voltage converter 10 according to an exemplary embodiment. The voltage converter 10 comprises a first printed circuit board 11 (PCB) and a second printed circuit board 12. A first circuit section 13 of the voltage converter 10 is arranged on the first printed circuit board 11, and a second circuit section 14 of the voltage converter is arranged on the second printed circuit board 12. The first circuit section 13 is electrically coupled to the second circuit section 14 by an electrical coupling 16. Even if the electrical coupling 16 is illustrated schematically as a single line in FIG. 1, it can comprise a multiplicity of individual electrical connections. The first circuit section 13 and the second circuit section 14 together form a voltage converter circuit, in particular a DC-DC voltage converter circuit. The first and second circuit sections can each contain discrete components, for example capacitors, resistors, transistors, coils, transformers, etc., components realized in metal layers of the respective printed circuit board, such as coils, or else integrated circuits.

The first circuit section 13 has one or more semiconductor chips 15 embedded between metal layers of the first printed circuit board 11. These semiconductor chips can contain, in particular, one or more transistors which can serve, for example, as switches in the voltage converter. Such transistors can be implemented on the basis of silicon or else on the basis of other semiconductor materials. For example, semiconductor materials with a large band gap, such as, for example, GaN transistors such as GaN HEMTs (high electron mobility transistor), can be used.

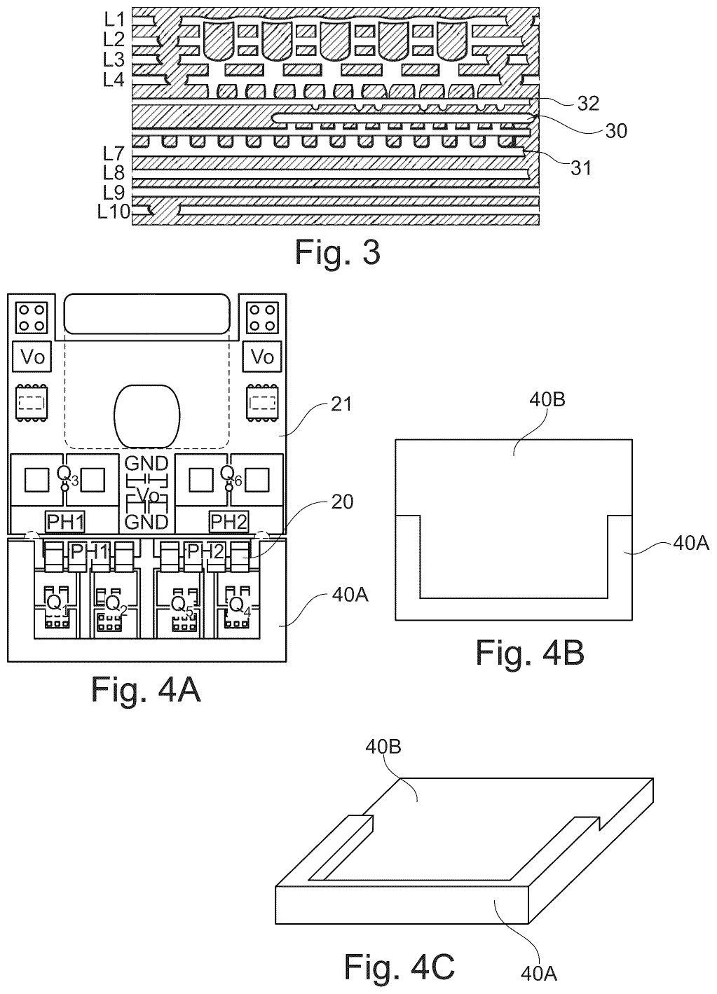

For illustration, FIG. 3 shows, in this case, a construction in which a semiconductor chip 30 is embedded between metal layers 31, 32 of a printed circuit board. L1-L4 and L7-L10 denote further metal layers which, as illustrated, can be connected to one another by vertical connections. The illustrated configuration of the metal layers is to be understood here only as an example, and the metal layers can be configured as is required for a respective wiring of the semiconductor chip and of the rest of the first circuit section. The metal layers are separated from one another, as customary, by dielectrics and, as can be seen in particular in the metal layers 32, can be connected to one another by vertical connections (for example VIAs, Vertical Interconnect Access).

The dielectric between the metal layers likewise provides an encapsulation for the chip 30, while the chip 30 is electrically connected to metal layers by corresponding contact-connections.

As a result, larger semiconductor chips can be used than with non-embedded semiconductor chips which, for example, still require a separate package. For example, chips (dies) can be used here which have a chip area of greater than 7 mm², greater than 8 mm², greater than 10 mm² or greater than 12 mm², while in conventional solutions with discrete elements on a printed circuit board, with the same total space available, only smaller chips can be used. This makes it possible, for example, to increase a number of transistors with the same area and thus to provide voltage converters for higher powers, higher voltages and/or higher currents.

The first circuit section 13 can be designed to carry lower currents during operation of the voltage converter than the second circuit section. In typical switching voltage converter implementations, there are circuit parts which carry relatively low currents, for example because they essentially only switch voltage potentials, while other parts carry higher currents, in particular an output section from which a load is supplied with power. In this way, the respective printed circuit boards can be matched with regard to their construction to the different current carrying requirement.

Thus, a number of metal layers in the first circuit board 11 can be smaller than a number of metal layers in the second circuit board 12. The use of semiconductor chips embedded between metal layers of the first circuit board 11 can require a larger spacing of metal layers. On the other hand, if, as mentioned above, the first circuit section carries lower currents than the second circuit section, fewer metal layers can be sufficient to carry the current with low losses. Thus, for example, the first circuit board 11 can have between 6 and 10 metal layers, while the second circuit board 12 can have between 16 and 20 metal layers.

These metal layers of the second circuit board 12 can have a smaller spacing than a spacing between the metal layers of the first circuit board 11, so that a higher metal content results here. The metal can be, in particular, copper, as customary in circuit boards, which conducts the current particularly well. In this way, losses in the second circuit board 12 can be kept lower, since, owing to the higher metal content, larger conduction cross sections can be provided in order to carry current in the second circuit board 12. Also, one or more coils designed for high currents can be implemented in the metal layers of the second circuit board 12, for example in the form of individual coils or transformers such as autotransformers or planar transformers. Here, one or more turns of such a coil can also extend in parallel over a plurality of metal layers.

Owing to the smaller number of metal layers, the first circuit board 11 can also be thinner overall than the second circuit board 12, which can offer more space for components on the first circuit board or else at other locations.

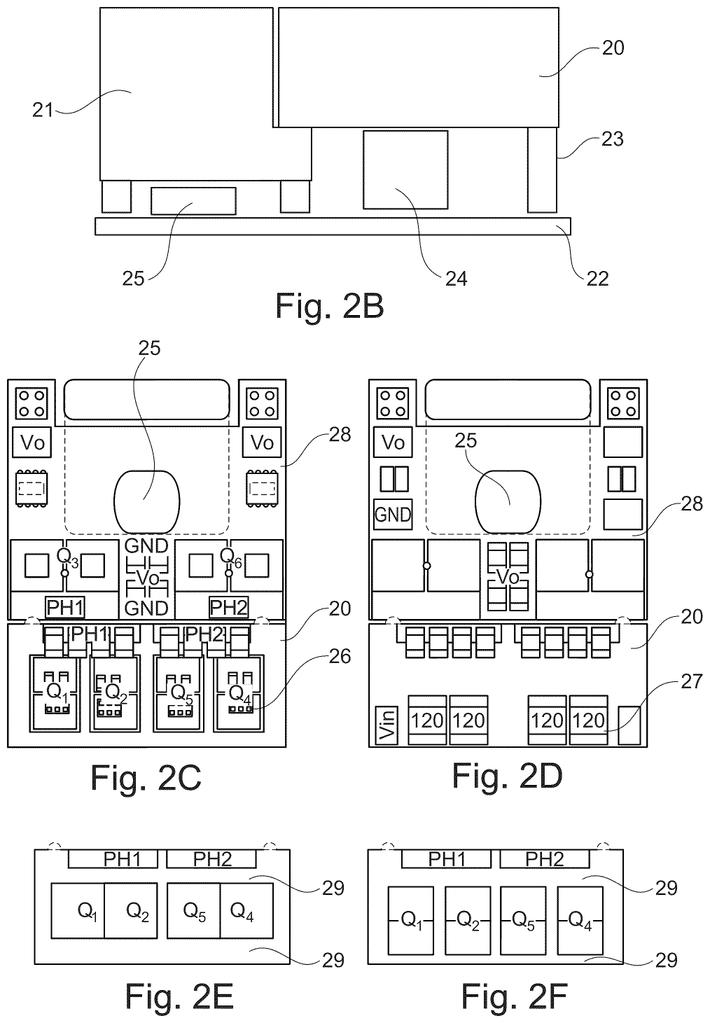

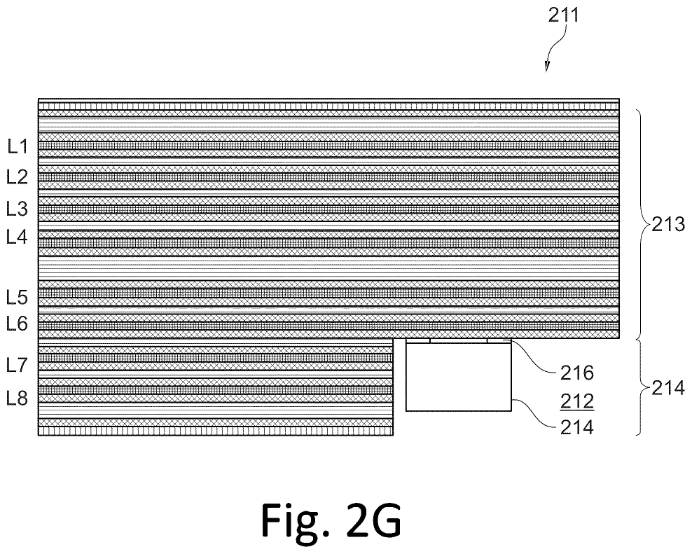

The first circuit board 11 and the second circuit board 12 can be arranged above a third circuit board. A corresponding exemplary embodiment will now be explained with reference to FIGS. 2A to 2D.

FIG. 2A shows a perspective view, and FIG. 2B shows a side view of a voltage converter according to an exemplary embodiment. The voltage converter comprises a first circuit board 20 and a second circuit board 21, which are electrically and mechanically coupled in a coupling region 210. As can be seen in particular in FIG. 2B, the second circuit board 21 here has a step-shaped cutout, into which the first circuit board engages.

The first circuit board 20 and the second circuit board 21 are arranged above a third circuit board 22 and spaced apart therefrom by supporting elements 23. The elements 23 here can also have or form electrical connections in order to electrically couple the assembly of first circuit board 20 and second circuit board 21 to the third circuit board 22 and components located thereon.

The third circuit board 22 can have comparatively few metal layers, for example 4 metal layers, in particular fewer metal layers than the first circuit board 20 and the second circuit board 21, and can have dimensions as required for the use of the voltage converter in a system, for example the above-mentioned dimensions of 23 mm×17 mm, which is a quasi-standard for DC/DC converters for AI applications. As shown in FIG. 2B, components 24, 25 which serve for communication with a respective system in which the voltage converter is used can be provided on the third circuit board 22. The components 24, 25 can have a greater height under the first circuit board 20 than under the second circuit board 21, since the first circuit board 20 is thinner.

FIG. 2C shows an exemplary view of the first and second circuit boards 20, 21 from above, that is to say from the side facing away from the third circuit board 22, and FIG. 2D shows a corresponding view from below. FIGS. 2E and 2F show sectional views of the first circuit board 20 which has embedded semiconductor chips. As can be seen from FIGS. 2C and 2D, various components can be arranged on both sides of the first circuit board 20 and of the second circuit board 21. This contains integrated circuits 28 and transistor elements Q₃, Q₆ and a coil arrangement 25 for the second circuit board 21 and, for example, capacitors 27 and driver circuits 26 for transistors of embedded transistor chips (see FIGS. 2E and 2F) for the first circuit board 20. The capacitors 27 can be dimensioned larger than in some conventional implementations owing to the smaller thickness of the first circuit board 20. The first circuit board 20 and the second circuit board 21 communicate with one another via contact elements PH 1, PH 2. As shown in the sectional views of FIGS. 2E and 2F, transistor chips Q₁, Q₂, Q₄ and Q₅ are embedded in the first circuit board 20 between metal layers 29 (illustrated above and below the transistor chips in the view of FIGS. 2E and 2F), wherein two cavities are provided between the metal layers in FIG. 2E, wherein two chips are arranged in each cavity (Q₁, Q₂ in the first cavity and Q₄, Q₅ in the second cavity), while four cavities are provided in FIG. 2F, wherein two chips are also arranged in each cavity here. The case of FIG. 2F corresponds to the case which is also indicated in FIG. 2C.

Circuit elements such as the capacitors 27 can then be arranged completely or partially above the semiconductor chips, which leads to short connection paths between transistors in the semiconductor chips and the capacitors and thus to low parasitic capacitances.

In a further embodiment, the circuit boards 20 and 21 are not embodied separately but are configured in a single circuit board 211. This single circuit board 211 shows regions of different thicknesses in the illustrated cross section. In this embodiment, the metal layers and other layers lying between the metal layers, for example dielectrics, as shown in FIG. 2G, are embodied in 2 or more different lengths. In the exemplary embodiment of FIG. 2G, in this case the layers including metal layers L 1 to L 6 are longer in a region 213 than layers including metal layers L 7 and L 8 in a region 214. As a result, a usable cutout 212 is formed. The division of the metal layers onto the regions is in this case only one example, and other divisions can also be selected. For example, both regions 213, 214 can each have the same number of metal layers or different numbers of metal layers, and the number of metal layers present overall can vary.

The cutout 212 can accommodate circuit elements 215 such as capacitors or else relatively small printed circuit boards with corresponding electrical circuits in a space-saving manner.

In particular, the electrical components introduced or located on the introduced printed circuit board can conduct higher currents than the components which are accommodated on the remaining, larger printed circuit board 211.

The circuit elements 214 which are introduced into the cutout can be connected directly to an adjoining metal layer, in this case the metal layer L7, by means of electrical connections 216. In this way, relatively large components below the thinner region of a printed circuit board can also be integrated in a space-saving manner.

In other exemplary embodiments, the printed circuit board 211 is arranged above a further printed circuit board (e.g. the printed circuit board 22 described above), and the circuit elements 214 can additionally or alternatively be electrically connected to this further printed circuit board.

The use of the printed circuit board 211 is not limited to voltage converters.

A printed circuit board is therefore provided, comprising a multiplicity of metal layers which are arranged one above the other in a first direction, wherein metal layers of the multiplicity of metal layers in a first region which extends in the first direction have a smaller extent in at least one second direction which is different from the first direction than metal layers of the multiplicity of metal layers in a second region which is different from the first region and likewise extends in the first direction. A cutout can thus be formed. One or more circuit elements can be provided in the cutout. The circuit elements can be electrically coupled to one of the multiplicity of metal layers, in particular one of the metal layers in the first region.

During operation of voltage converters, heat arises, for example, as a result of switching losses or flow of high currents. In order to dissipate the heat, a cooling plate composed of a metal with good thermal conductivity, such as copper or aluminum, is conventionally arranged on the first and/or second circuit board. As a result of the use of embedded chips in the first circuit board, a more compact arrangement is possible which allows additional thermally conductive elements to be arranged laterally on the first circuit board. A corresponding exemplary embodiment is illustrated in FIGS. 4A to 4C.

As shown in FIG. 4A, thermally conductive material 40 A laterally surrounds the first circuit board 20 on three sides. In this case, the thermally conductive element 40 A can be produced, in particular, from a metal. As shown in FIGS. 4B and 4C, the thermally conductive element 40 A can be connected to a plate 40 B which, like a conventional cooling plate, is arranged above the first circuit board 20 and optionally also above a part of the second circuit board 21, for example the region of the transistors Q₃, Q₆. Thus, in such exemplary embodiments, compared with the mere provision of a cooling plate, additional cooling can be provided.

Various variants are possible for the coupling of the first circuit board to the second circuit board. One possible example is shown in FIGS. 5A and 5B. In this case, FIG. 5A shows an example of a second circuit board 51, for example the second circuit board 21 or 12 from the preceding figures, and FIG. 5B shows an example of a first circuit board 50 with embedded chips 52, which can be an example of the first circuit board 11 or 20. In the illustrated example, the first circuit board 50 has two projections 55, and the second circuit board 51 has two corresponding notches 53. In the assembled state, the projections 55 engage in the notches 53, with which exact positioning can be achieved. In addition, the first circuit board 50 has electrical contacts 56 and the second circuit board 51 has electrical contacts 54 which, during this positioning, come into contact with one another and thus electrically connect the respective first circuit section to the respective second circuit section. The number of contacts 56 and contacts 54 and the arrangement thereof match one another in this case, but with regard to the arrangement and number is otherwise to be understood only as an example, that is to say more or fewer electrical contacts can also be provided as required for the respective voltage converter circuit. Also, the shape, number and positioning of the projections 55 and of the corresponding notches 53 is to be understood only as an example. In addition, fastening means such as clips and the like can also be provided in order to form a fixed connection.

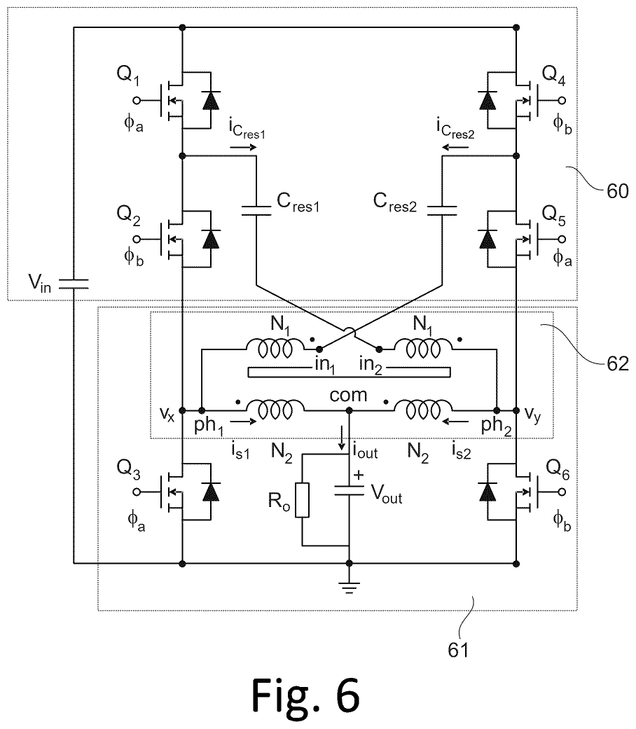

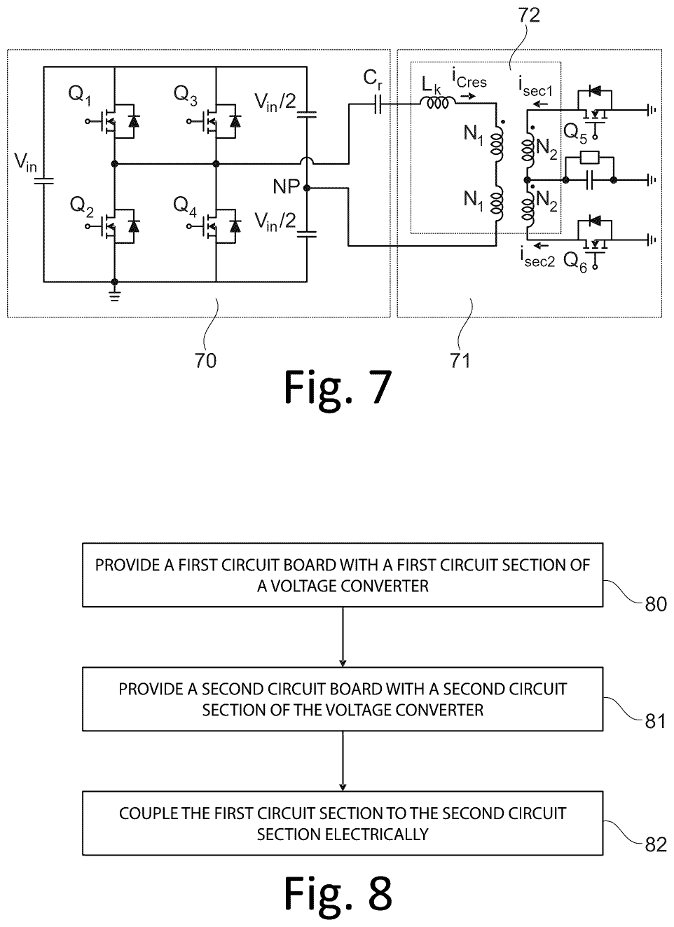

As already explained, various voltage converters can be used. FIGS. 6 and 7 show two different possible circuit topologies.

FIG. 6 shows an example of a so-called HSC converter (hybrid switch capacitor converter) which is based on a resonant converter having two phases. A circuit section 60 carries low current during operation and is an example of a first circuit section which can be realized on a first circuit board (e.g. 11, 20 or 50), and a circuit section 61 is an example of a second circuit section which can be realized on a second circuit board (e.g. 12, 21 or 51). Transistors Q₁, Q₂, Q₄ and Q₅ of the first circuit section 60 can be implemented by means of embedded semiconductor chips, and the capacitors C 1 and C: then correspondingly as discrete capacitors which are arranged partially above the semiconductor chips. A coil arrangement 62 of the second circuit section 61, which forms a transformer, represents an example of a coil arrangement which can be realized by means of one or more turns in metal layers of the second circuit board.

FIG. 7 shows an example of an LLC half-bridge converter. Here, a first circuit section 70 can in turn be realized on the respective first circuit board, and a second circuit section 71 can be realized on the respective second circuit board. Transistors Q₁ to Q₄ of the first circuit section 70 can be implemented as embedded chips, and the illustrated capacitors can in turn be realized as discrete capacitors. A coil arrangement 72 including a capacitor in turn represents an example of elements which can be realized within the metal layers of the second circuit board.

FIG. 8 shows a flow chart of a method for producing a voltage converter according to some exemplary embodiments. The method of FIG. 8 can serve, for example, for producing the voltage converters described above and is described with reference thereto.

In step 80, a first circuit board with a first circuit section of a voltage converter is provided, wherein for this purpose semiconductor chips are embedded between metal layers of the first circuit board. The first circuit board can be the first circuit board of any of the exemplary embodiments described above.

In step 81, a second circuit board with a second circuit section of the voltage converter is provided. The second circuit board can be the second circuit board of any of the exemplary embodiments described above. Steps 80 and 81 can also be carried out in reverse order or in parallel. At 82, the first circuit section is then electrically coupled to the second circuit section, for example as described above, in particular with reference to FIGS. 5A and 5B.

The assembly of first circuit board and second circuit board can then also be arranged above a third circuit board, as illustrated in FIG. 2A.

Some embodiments are defined by the following examples:
Example 1. Voltage converter, comprising:
a first circuit board with a first circuit section of the voltage converter, wherein the first circuit section comprises semiconductor chips embedded between metal layers of the first circuit board, and
second circuit section a second circuit board with a second circuit section of the voltage converter, wherein the first circuit section is electrically coupled to the second circuit section.
Example 2. Voltage converter according to Example 1, wherein the first circuit section is designed to carry lower currents during operation of the voltage converter than the second circuit section.
Example 3. Voltage converter according to Example 1 or 2, wherein a number of metal layers of the first circuit board is smaller than a number of metal layers of the second circuit board.
Example 4. Voltage converter according to one of Examples 1 to 3, wherein the second circuit section comprises one coil or a plurality of coils.
Example 5. Voltage converter according to one of Examples 1 to 4, wherein the first circuit board and the second circuit board have mechanical and electrical coupling elements which are configured to mechanically couple the first and the second circuit board and to provide the electrical coupling of the first circuit section to the second circuit section.
Example 6. Voltage converter according to Example 5, wherein the mechanical coupling elements comprise a step-shaped cutout in one of the first and the second circuit board, and wherein the other of the first and second circuit board can be fitted into the step-shaped cutout.
Example 7. Voltage converter according to one of Examples 1 to 6, wherein the semiconductor chips contain transistors, wherein the first circuit board additionally comprises capacitors arranged at least partially overlapping with the transistors in a top view.
Example 8. Voltage converter according to one of Examples 1 to 7, wherein the first circuit board comprises one side wall or a plurality of side walls made of thermally conductive material.
Example 9. Voltage converter according to Example 8, wherein the plurality of side walls form a U-shape.
Example 10. Voltage converter according to one of Examples 1 to 9, wherein the semiconductor chips have an area of greater than 7 mm².
Example 11. Voltage converter according to one of Examples 1 to 10, further comprising a third circuit board with contact elements which are configured to connect the voltage converter to a system containing the voltage converter, wherein the first circuit board and the second circuit board are arranged above the third circuit board.
Example 12. Voltage converter according to one of Examples 1 to 11, wherein the second circuit board does not have embedded semiconductor chips.
Example 13. Method for producing a voltage converter, comprising:
providing a first circuit board with a first circuit section of the voltage converter s, wherein the first circuit section comprises semiconductor chips embedded between metal layers of the first circuit board,
providing a second circuit board with a second circuit section of the voltage converter s, and
electrically coupling the first circuit section to the second circuit section.
Example 14. Method according to Example 13, wherein the method for producing the voltage converter is configured according to one of Examples 1 to 12.

Although specific embodiments have been illustrated and described in this description, persons with common technical knowledge will recognize that a multiplicity of alternative and/or equivalent implementations may be chosen as a substitution for the specific embodiments shown and described in this description without departing from the scope of the invention shown. It is the intention that this application covers all adaptations or variations of the specific embodiments discussed herein. Therefore, it is intended that this invention be limited only by the claims and the equivalents of the claims.

1. A voltage converter comprising:
a first circuit board including a first circuit section, wherein the first circuit section comprises semiconductor chips embedded between metal layers of the first circuit board; and
a second circuit board including a second circuit section electrically coupled to the first circuit section.

2. The voltage converter according to claim 1, wherein the first circuit section is configured to carry lower currents during operation of the voltage converter than the second circuit section.

3. The voltage converter according to claim 1, wherein a number of the metal layers of the first circuit board is smaller than a number of metal layers of the second circuit board.

4. The voltage converter according to claim 1, wherein the second circuit section comprises at least one coil.

5. The voltage converter according to claim 1, wherein the first circuit board and the second circuit board have mechanical and electrical coupling elements which are configured to mechanically couple the first and the second circuit board and to provide the electrical coupling of the first circuit section to the second circuit section.

6. The voltage converter according to claim 5, wherein the mechanical coupling elements comprise a step-shaped cutout in one of the first circuit board and the second circuit board, and wherein the other of the first and second circuit board can be fitted into the step-shaped cutout.

7. The voltage converter according to claim 1, wherein the semiconductor chips include transistors, wherein the first circuit board additionally comprises capacitors arranged at least partially overlapping with the transistors in a top view.

8. The voltage converter according to claim 1, wherein the first circuit board comprises at least one side wall fabricated from thermally conductive material.

9. The voltage converter according to claim 8, wherein the plurality of side walls form a U-shape.

10. The voltage converter according to claim 9, wherein the semiconductor chips have an area of greater than 7 mm².

11. The voltage converter according to claim 1, further comprising a third circuit board with contact elements which are configured to connect the voltage converter to a system containing the voltage converter, wherein the first circuit board and the second circuit board are arranged above the third circuit board.

12. The voltage converter according to claim 1, wherein the second circuit board does not have embedded semiconductor chips.

13. A method comprising:
receiving a first circuit board with a first circuit section, wherein the first circuit section comprises semiconductor chips embedded between metal layers of the first circuit board;
receiving a second circuit board with a second circuit section of the voltage converters; and
electrically coupling the first circuit section to the second circuit section.
